(19) United States
(12) Patent Application Publication
(10) Pub. No.: US 2024/0405089 A1
(43) Pub. Date: Dec. 5, 2024

(54) LATERAL GATE-ALL-AROUND TRANSISTORS, THREE-DIMENSIONAL INTEGRATED CIRCUIT, AND MANUFACTURING METHOD THEREOF

(71) Applicant: BEIJING INSTITUTE OF TECHNOLOGY, Beijing (CN)

(72) Inventors: Shujun YE, Beijing (CN); Yeliang WANG, Beijing (CN)

(21) Appl. No.: 18/798,337

(22) Filed: Aug. 8, 2024

Related U.S. Application Data
(63) Continuation of application No. PCT/CN2023/094667, filed on May 17, 2023.

(30) Foreign Application Priority Data
Jul. 5, 2022 (CN) 202210846206.4

(51) Int. Cl. H01L 29/423; H01L 27/092; H01L 29/417; H01L 29/66; H01L 29/775; H01L 29/786

(52) U.S. Cl. CPC H01L 29/42392; H01L 27/092; H01L 29/41733; H01L 29/66439; H01L 29/775; H01L 29/7869; H01L 29/78696

(57) ABSTRACT

Vertically superimposed lateral gate-all-around metal-oxide-semiconductor field-effect transistors are provided, a structure of a novel three-dimensional integrated circuit such as a CMOS logic circuit that is composed of the vertically superimposed lateral gate-all-around transistors, a random-access memory and the like, and a manufacturing method for the novel three-dimensional integrated circuit are provided. The manufacturing method for the vertically superimposed lateral gate-all-around transistors includes: first preparing a monolayer channel and a source/drain, then protected with a sacrificial layer; preparing an insulating isolation layer, preparing above repeated structures on the insulating isolation layer; preparing an insulating spacer layer between the source/drain and a gate of each of the layers, a gate oxide, a gate, and a source/drain electrode in a unified manner, and finally preparing a connecting wire connected to the outside. The novel three-dimensional integrated circuit can be implemented by connecting the lateral gate-all-around transistors by means of a wire.

### CROSS-REFERENCE TO RELATED APPLICATION

This application is a by-pass continuation application of International Patent Application No. PCT/CN2023/094667, filed May 17, 2023, which claims priority of the Chinese Patent Application No. 202210846209.4, filed with the China National Intellectual Property Administration on Jul. 5, 2022, and entitled “Lateral gate-all-around transistors, three-dimensional integrated circuit, and manufacturing method thereof”, both of which are incorporated by references in their entities.

### TECHNICAL FIELD

The present disclosure relates to the field of core devices of integrated circuits, in particular to a gate-all-around metal-oxide-semiconductor field-effect transistor, and a novel three-dimensional integrated circuit, such as a CMOS logic device and a random access memory MRAM, composed of gate-all-around metal-oxide-semiconductor field-effect transistors, and a manufacturing method thereof.

### BACKGROUND

The core device of the integrated circuit is metal-oxide-semiconductor field-effect transistors (MOSFET, referred to as transistors in the proposal of the present disclosure). The pursuit of integrated circuits is high integration level (also high density), high speed, and low energy consumption, which are usually achieved by reducing the size of transistors. In recent 50 years, Moore's law has successfully guided the reduction of the size of transistors. However, at present, the size of transistors is difficult to further reduce due to a limit of characteristics in process and physics. Meanwhile, the size reduction of the device may cause another problem, that is, a short-channel effect capable of increasing the energy consumption is produced. For the above problem, a three-dimensional structure can increase the control of the gate on the channel and reduce the short-channel effect. Fin structure has become the main structure of integrated circuits. Further, according to the prediction of the International Roadmap for Devices and Systems (IRDS), gate-all-around (GAA) transistors will become the main devices of the next-generation integrated circuits due to their greatest control on the channel current.

Lateral gate-all-around metal-oxide-semiconductor field-effect transistors (referred to as lateral gate-all-around transistors) have been applied in the logic circuit of 3 nm technology node by top enterprises in the industry such as TSMC and Samsung. Theoretically, the short-channel effect can be minimized by using silicon nanowires as channels of lateral gate-all-around transistors. However, due to the capacity limitation of the existing semiconductor technology, nanosheets are widely used as the channels of lateral gate-all-around transistors by the enterprises. There are two main purposes of using nanosheets: one is that nanosheets have greater mechanical strength than that of silicon nanowires, thus are not easy to deteriorate in the manufacturing process of transistors; and the other is that nanosheets have larger outer-surface circumference than that of silicon nanowires, which can increase the transmission current of the channel. However, the nanosheets have a larger device area, which is not conducive to the improvement of integration level. In addition, due to the existing process, material characteristics and other reasons, multilayer nanosheet channels are usually prepared in the vertical direction for one lateral gate-all-around transistor to use. Therefore, the lateral gate-all-around transistor has no advantage in integration level compared with the previous planar transistor and the widely used fin transistor.

At present, three-dimensional structure is employed as the main method for increasing the integration level of integrated circuits. The technology of directly vertically superimposing wafers and chips has been applied in products of actual chips, but even with the most advanced technology, the distance between superimposed wafers or chips is difficult to be less than 10 microns. Therefore, the resistance and delay caused by this distance are hard to ignore for the transistors with a length of gate below tens of nanometers. In another Complementary FETs (CFETs) technology developed by Intel, IBM, etc., the CMOS is prepared by superimposing PMOS on NMOS, or superimposing NMOS on PMOS, thus better improving the integration level. However, there are two problems in CFETs. One is that the prepared PMOS and NMOS are required to be compatible in process, and the other is that it is difficult to prepare more than two layers due to problems such as compatibility in process, that is, the integration level is limited.

In conclusion, lateral gate-all-around transistors, as the main device of the next-generation integrated circuits, face the problem of low integration level.

### SUMMARY

For the problem of low integration level faced by a lateral gate-all-around transistor as a main device of the next-generation integrated circuit, a new structure prepared by superimposing multiple layers of lateral gate-all-around transistors in a vertical direction, and a process for the new structure are provided in the present disclosure. A semiconductor device (a CMOS logic device, a static random-access memory (SRAM), etc.) composed of the multiple layers of superimposed lateral gate-all-around transistors, and an integrated circuit composed of the semiconductor devices, and a manufacturing method for the semiconductor device and the integrated circuit are provided.

Specifically,
the present disclosure provides the following structure:
A three-dimensional integrated circuit having a structural feature that multiple layers of lateral gate-all-around metal-oxide-semiconductor field-effect transistors (referred to as lateral gate-all-around transistors) are superimposed and isolated by an insulating isolation layer in a direction perpendicular to a substrate is provided. the multiple layers of lateral gate-all-around transistor include channels implanted with ions of a same type, and a thickness of the insulating isolation layer for isolating between the multiple layers of lateral gate-all-around transistors has a thickness that does not exceed 10,000 nanometers.

The following supplementary explanations are made for the above contents:
The thickness of the insulating isolation layer is determined by the current process level of superimposing chips and superimposing wafers. Although the process of superimposing the chips, superimposing the wafers or chips is widely used in three-dimensional integrated circuit, a distance between adjacent layers is difficult to be less than 10000 nm due to factors such as process capability and mechanical strength of materials.

In addition, although CFETs is a superposition of devices, the superposition is the superposition of heterostructures, that is, PMOS is superimposed on NMOS, or NMOS is superimposed on PMOS, rather than the superposition of channels implanted with ions of a same type provided by the present disclosure.

In the integrated circuit with the above structure, the following structural features are further provided, specifically, the channels of the lateral gate-all-around transistors in adjacent layers in a direction perpendicular to the substrate are parallel to each other and are equal in length, and a channel within each layer of the lateral gate-all-around transistors may be a multichannel structure, or a single-channel structure.

The following supplementary explanations are made for the above contents:
In this disclosure, a situation that the channels of the lateral gate-all-around transistors in adjacent layers in a direction perpendicular to the substrate are parallel to each other and are equal in length is determined by a process for simultaneously preparing gate oxides and gates of the superimposed lateral type gate-all-around transistors. In the manufacturing process, it is required that the channels are parallel to each other and are equal in length. It should be noted that strict equality is difficult to achieve in the real world, and length equality needs to consider the errors of existing preparation processes and measuring tools, that is, the equality has certain tolerance for errors caused by objective environment. The description of equality here is applicable to other parts and similar words in the present disclosure, such as the same.

Furthermore, for different layers, as the channels of different layers are designed and manufactured separately, whether the channel of each layer is a single-channel or multi-channel depends on the design. Therefore, the proposal of the present disclosure also has great flexibility.

In the integrated circuit with above structure, the following structural features are further provided, specifically, when the channel of the lateral gate-all-around transistor in any layer is projected on the substrate to form a plane pattern, a distance between any boundary of the plane pattern parallel to a channel direction and any boundary of a plane pattern, which is formed by projecting a channel of the lateral gate-all-around transistor in adjacent layer on the substrate, parallel to a direction of the adjacent channel is less than 500 nanometers.

The following supplementary explanations are made for the above contents:
When the process provided in the present disclosure is used to design or prepare multiple layers of superimposed gate-all-around transistors in a vertical direction, the channel of one certain layer may be a single-channel or multi-channel. Even if channels of all the layers are single-channel, a projection of the channel of each one of the layers on the substrate may not necessarily overlapped completely. The above content also indicates that the process provided in the present disclosure also has great flexibility.

In the integrated circuit with the above structure, the following structural features are further provided, specifically: the channels of the lateral gate-all-around transistors in the adjacent layers are same in number, shape, size, and ion implantation concentration.

The following supplementary explanations are made for the above contents:

Here, the above content is also determined by the process and the characteristics of integrated circuits used on a large scale. The usual large-scale integrated circuits require the repetition of the same devices, which can be completely satisfied by the process provided in the present disclosure. Therefore, the proposal of the present disclosure has great practicability in large-scale integrated circuits.

Based on the following features of the above structures,

An integrated circuit having a structure that multiple layers of lateral gate-all-around metal-oxide-semiconductor field-effect transistors implanted with the same ion are superimposed and isolated by the insulating isolation layer in a direction perpendicular to the substrate is provided, and a thickness of the insulating isolation layer for isolating between the multiple layers of lateral gate-all-around transistors has a thickness that does not exceed 10,000 nanometers.

The following structural features are further provided:
any one of a semiconductor device formed by connecting the lateral gate-all-around transistors within each layer through a wire, a semiconductor device formed by connecting between the multiple layers of lateral gate-all-around transistors through a wire, and a semiconductor device formed by connecting the lateral gate-all-around transistors within each layer, and the multiple layers of lateral gate-all-around transistors through wires.

The following supplementary explanations are made for the above contents:
According to the process provided in the present disclosure, not only vertically superimposed lateral gate-all-around transistors may be prepared, but also semiconductor devices (CMOS logic circuit, and static random-access memory SRAM, etc.) composed of the lateral gate-all-around transistors may be prepared, and a three-dimensional integrated circuit composed of the semiconductor devices may also be prepared. The proposal provided in the present disclosure is strong in universality, compatibility, practicability, and importance.

For the above multiple layers of vertically superimposed gate-all-around transistors, the semiconductor devices (CMOS logic circuits, random access memory SRAM, etc.) composed of the lateral gate-all-around transistors, and the three-dimensional integrated circuits composed of the semiconductor devices, a manufacturing method including the following main steps is provided:
1.1. depositing an insulating layer on a substrate;
1.2. depositing a sacrificial protective layer on the insulating layer, depositing a channel layer doped with ions on the sacrificial protective layer, and depositing a sacrificial protective layer on the channel layer doped with ions;
1.3. depositing an insulating protective layer on the sacrificial protective layer;
1.4. forming a required channel pattern on a structural body in Step 1.3 through a process of semiconductor etch;
1.5. depositing the sacrificial protective layer in Step 1.2 on the structural body in Step 1.3, wearing and smoothening the sacrificial protective layer until an upper surface of the structural body in Step 1.3 is completely covered with the sacrificial protective layer;
1.6. depositing an insulating isolation layer on the worn and smoothened sacrificial protective layer;
1.7. repeating the above steps from 1.2 to 1.6 to form a basic framework with a required number of layers;
1.8. depositing a protective film to protect a channel part in a middle of the basic framework;
1.9. etching away a sacrificial protective layer exposed out of the protective film at both ends of a structural body in Step 1.8;
1.10. depositing polysilicon on a part etched in Step 1.9;
1.11. depositing the same protective film as that in Step 1.8 on a structural body in Step 1.10 for protection;
1.12. etching away a protective film at a middle channel part;
1.13. etching away the sacrificial protective layer around the middle channel part;
1.14. forming an insulating spacer layer between a gate and a source/drain electrode;
1.15. forming a gate oxide;
1.16. forming a gate;
1.17. protecting a structure formed in Step 1.16 with the same protective film as in Step 1.11;
1.18. etching away a protective film at both ends;
1.19. etching away the polysilicon formed in Step 1.10;
1.20. forming a source/drain electrode at a hole left after etching in Step 1.19;
1.21. on a plane parallel to the substrate, etching a periphery of a structure body formed in Step 1.20, on a plane parallel to the substrate, to remove a connecting and conducting part between layers when the gate is deposited in Step 1.16 and when the source/drain electrode is deposited in Step 1.20, thus forming multiple layers of lateral gate-all-around transistors isolated by the insulating isolation layer formed in Step 1.6;
1.22. wrapping a structure in Step 1.21 with an insulating material; and
1.23. forming a connecting wire between each layers of lateral gate-all-around transistors and the outside world using a semiconductor etch technology, thus forming a final structure with multiple layers of gate-all-around transistors.

The following supplementary explanations are made for the above contents:
Here, the vertically superimposed lateral gate-all-around transistors, the semiconductor devices (CMOS logic circuits, random access memory SRAM, etc.) composed of the lateral gate-all-around transistors, and the most basic and currently unique manufacturing process for the three-dimensional integrated circuits composed of the semiconductor devices are provided in the present disclosure.

The claims of the present disclosure only describe the main steps, while the order of a part of the main steps can be adjusted without affecting the ultimate purpose.

For the above multiple layers of vertically superimposed lateral gate-all-around transistors, the semiconductor devices (CMOS logic circuits, random access memory SRAM, etc.) composed of the lateral gate-all-around transistors, and the three-dimensional integrated circuits composed of the semiconductor devices, a manufacturing method including the following main steps is provided:
Depositing polysilicon around the source and drain, where one end, close to the channel, of polysilicon is configured for thermal oxidation to form an insulating spacer layer between the gate and the source/drain electrode, and another end of the polysilicon is etched away for depositing the source/drain electrode in the later stage of the process.

The following supplementary explanations are made for the above contents:
Here, the rights are protected for an original method for using polysilicon to prepare an insulating spacer layer between the gate and the source/drain electrode and to serve as a preliminary intermediate layer of the source/drain electrode.

For the above multiple layers of vertically superimposed lateral gate-all-around transistors, the semiconductor devices (CMOS logic circuits, random access memory SRAM, etc.) composed of the lateral gate-all-around transistors, and the three-dimensional integrated circuits composed of the semiconductor devices, a manufacturing method including the following main steps is provided:
By utilizing the characteristics that an oxide film formed by thermally oxidizing silicon block including the polysilicon is thick and requires long etching time during the thermal oxidization of the silicon nanowires of the channel and the silicon blocks including the polysilicon, after the silicon nanowires and the silicon blocks including the polysilicon are thermally oxidized, the oxide on the surface of the silicon nanowires is removed, and the residual oxide is used to form the insulating spacer layer between the gate and the source/drain electrode.

The following supplementary explanations are made for the above contents:
Here, an original method for forming an insulating spacer layer between the gate and the source/drain electrode by means of thermal oxidation is protected.

For the above multiple layers of vertically superimposed lateral gate-all-around transistors, the semiconductor devices (CMOS logic circuits, random access memory SRAM, etc.) composed of the lateral gate-all-around transistors, and the three-dimensional integrated circuits composed of the semiconductor devices, a manufacturing method including the following features and main steps is provided, including any one of the following methods:
After completing the gates of the multiple layers of lateral gate-all-around transistors, the periphery of a structural body on a plane parallel to the substrate is etched, and a conducting part of the gates between each layers is removed to achieve the separation of the gates of each layers.

After completing the source/drain electrode of the multiple layers of lateral gate-all-around transistor, the periphery of the structural body on the plane parallel to the substrate is etched, and a conducting part of the source/drain electrodes between each layers is removed to achieve the separation of the source/drain electrodes of each layers.

After the gates and source/drain electrodes of the multiple layers of superimposed lateral gate-all-around transistors are deposited, the periphery of the structural body on the plane parallel to the substrate is etched, and conducting parts of the gates and the source/drain electrodes between each layers are removed to achieve the separation of the gates and the source/drain electrodes of each layers.

The following supplementary explanations are made for the above contents:
Here, an original method for etching the periphery of the device to achieve the separation of sources/drains and gates of each layers is protected.

By utilizing the structure and the preparation method provided in the present disclosure, the following effects can be produced:
Firstly, the integration level of the integrated circuit is significantly improved. As the gate-all-around transistor is the core device of the next-generation integrated circuit, and many commonly used and important devices in the integrated circuit can be formed by the gate-all-around transistors, e.g., various CMOS logic devices (NOT gate, AND gate, NAND gate, OR gate, NOR gate, XOR gate, etc.), various memories such as SRAM, DRAM, and peripheral circuits including input and output. The superposition of the multiple layers of lateral gate-all-around transistors is achieved in the vertical direction, and these superimposed gate-all-around transistors can be combined into various semiconductor devices by the method provided in the present disclosure. Therefore, the integration level of the lateral gate-all-around transistors is improved, and the integration level of the next-generation integrated circuit is improved actually.

In addition, the channels of the conventional multi-channel gate-all-around transistor are formed in the vertical direction. Due to the semiconductor process, the vertical etching usually forms a non-cylindrical structure with a thinner bottom than the top, that is, the shapes of multiple channels of the vertically superimposed multi-channel lateral gate-all-around transistor formed by the current semiconductor process are uneven. As the gate voltages on the multiple channels of the vertically superimposed multichannel lateral gate-all-around transistor are the same, the uneven shapes of the multiple channels will lead to different current environments of each channel of the multiple channels, affecting the electrical characteristics of the lateral gate-all-around transistor as a whole, such as a threshold voltage and a sub-threshold slope. The multiple channels provided in the present disclosure are completed in the same one layer, and thus the uniformity is excellent. It should be noted that the multiple layers of lateral gate-all-around transistors are superimposed, and the channels of the superimposed lateral gate-all-around transistors are prepared layer by layer, which are not affected by the semiconductor etching process and cannot generate a non-cylindrical structure with a thinner bottom than the top. That is, the uniformity between the layers of the lateral gate-all-around transistors is excellent.

Because there are errors in any manufacturing process and any measurement, the words of equal length and the same in the present disclosure have a generally meaning and have a certain range to tolerate errors. The tolerance range depends on the specific conditions such as the measuring instruments used.

In conclusion, the structure and method provided in the present disclosure have the features of large flexibility, universality, and strong operability, are close to the actual production of the integrated circuit, and have a huge application prospect.

### BRIEF DESCRIPTION OF THE DRAWINGS

The following drawings are a brief description of the embodiments of the present disclosure, which can be adjusted, added or deleted according to the actual situation in the specific implementation process. Although not all the embodiments are listed here, the embodiments obtained by analogy and association based on the present disclosure all fall the scope of the present disclosure.

FIG. 1 is one of embodiments of the present disclosure, i.e., a longitudinal section diagram of a two-layer superimposed structure in a basic structure of vertically superimposed lateral gate-all-around transistors according to the present disclosure;

FIG. 2 is one of embodiments of the present disclosure, i.e., a schematic diagram of a three-dimensional integrated circuit with a three-layer superimposed structure of a CMOS phase inverter in a vertical direction, which is composed of vertically superimposed lateral gate-all-around transistors according to the present disclosure;

FIG. 3 is one of embodiments of the present disclosure, i.e., a structural schematic diagram of a three-dimensional CMOS NAND logic gate composed of vertically superimposed lateral gate-all-around transistors according to the present disclosure;

FIG. 4 is a partial process of an embodiment of a manufacturing method for superimposed lateral type gate-all-around transistors, i.e., a schematic diagram of a process for manufacturing a channel pattern of a first layer of multiple-layers superimposed lateral gate-all-around transistors;

FIG. 5 is a process continuing from FIG. 4 with respect to an embodiment of a manufacturing method for superimposed lateral type gate-all-around transistors according to the present disclosure, i.e., a schematic diagram of a process for depositing an isolation insulating layer SiO₂;

FIG. 6 is a process continuing from FIG. 5 with respect to an embodiment of a manufacturing method for superimposed lateral type gate-all-around transistors according to the present disclosure, i.e., a schematic diagram of a preliminary structural body prepared by repeating the steps of FIG. 4 and FIG. 5 for the superposition of two layers of lateral gate-all-around transistors and a process thereof,

FIG. 7 is a process continuing from FIG. 6 with respect to an embodiment of a manufacturing method for superimposed lateral type gate-all-around transistors according to the present disclosure, i.e., a schematic diagram of a process for etching a sacrificial protective layer;

FIG. 8 is a process continuing from FIG. 7 with respect to an embodiment of a manufacturing method for superimposed lateral type gate-all-around transistors according to the present disclosure, i.e., a schematic diagram of a process for forming an insulating spacer layer between a gate and a source/drain electrode by thermal oxidation;

FIG. 9 is a process continuing from FIG. 8 with respect to an embodiment of a manufacturing method for superimposed lateral type gate-all-around transistors according to the present disclosure, i.e., a schematic diagram of a process for forming a gate oxide, a gate, and a source/drain electrode.

### DETAILED DESCRIPTION OF THE EMBODIMENTS

The present disclosure is further described below in detail with reference to accompanying drawings and example description for embodiments.

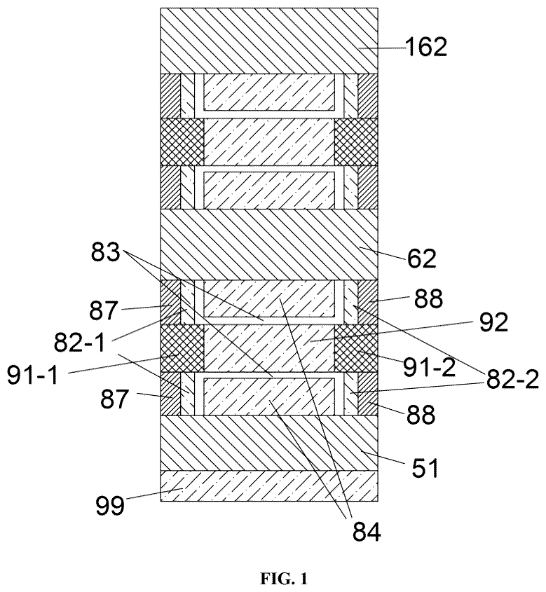

FIG. 1 is one of embodiments of the present disclosure, i.e., a schematic diagram of a two-layer superimposed structure in a basic structure of vertically superimposed lateral gate-all-around transistors according to the present disclosure. A substrate is indicated by reference number 99, and the substrate is generally made of silicon material. An insulating isolation layer is indicated by reference number 62, and two lateral gate-all-around transistors are arranged at upper and lower positions of the insulating isolation layer, respectively. The lower lateral gate-all-around transistor 51 is a bottom insulating layer. A covering protective film is indicated by reference number 162 in this figure, and the lateral gate-all-around transistor can be continuously superimposed on the covering protective film. A source and a drain of the lateral gate-all-around transistor are indicated by reference numbers 91-1 and 91-2, respectively. A channel of the lateral gate-all-around transistor is indicated by reference number 92. A gate oxide is indicated by reference number 83. A gate is indicated by reference number 84. Isolation insulating layers between the gate and a source electrode and between the gate and a drain electrode are indicated by reference numbers 82-1 and 82-2, respectively. 87 and 88 are the source electrode and the drain electrode are indicated by reference numbers 87 and 88, respectively.

The upper lateral gate-all-around transistor has the same structure as the lower lateral gate-all-around transistor.

Specifically, a three-dimensional integrated circuit includes a substrate 99, and a bottom insulation layer 51, a first lateral gate-all-around transistor, an insulating isolation layer 62, a second lateral gate-all-around transistor, and a cover protective film 162 superimposed on an upper surface of the substrate 99 in sequence.

The first lateral gate-all-around transistor includes a central pillar located at a central position of the first lateral gate-all-around transistor, and a cladding layer wrapped outside the central pillar.

The central pillar includes a channel 92 of the first lateral gate-all-around transistor, a first source 91-1, and a first drain 91-2. The first source 91-1 and the first drain 91-2 are located on both ends of the channel 92 of the first lateral gate-all-around transistor, respectively; the first source 91-1, the first drain 91-2 and the channel 92 of the first lateral gate-all-around transistor are located at the central position of the first lateral gate-all-around transistor.

The cladding layer includes a first gate oxide 83, a first gate 84, a first isolation insulating layer 82-1, a second isolation insulating layer 82-2, a source electrode 87, and a drain electrode 88. The source electrode 87, the first isolation insulating layer 82-1, the first gate 84, the second isolation insulating layer 82-2 and the drain electrode 88 are connected in sequence. The first gate oxide 83 is arranged between the first isolation insulating layer 82-1 and the first gate 84, between the first gate 84 and the second isolation insulating layer 82-2, and between the first gate 84 and the channel 92 of the first lateral gate-all-around transistor.

The second lateral gate-all-around transistor has the same structure as the first lateral gate-all-around transistor. That is, the second lateral gate-all-around transistor includes a central pillar located at a central position of the second lateral gate-all-around transistor, and a cladding layer wrapped outside the central pillar.

The central pillar includes a channel 92 of the second lateral gate-all-around transistor, a first source, and a first drain. The first source and the first drain are located on both ends of the channel of the first lateral gate-all-around transistor, respectively. The first source, the first drain and the channel of the first lateral gate-all-around transistor are located at the central position of the first lateral gate-all-around transistor.

The cladding layer includes a first gate oxide 83, a first gate 84, a first isolation insulating layer 82-1, a second isolation insulating layer 82-2, a source electrode 87 and a drain electrode 88; the source electrode 87, the first isolation insulating layer 82-1, the first gate 84, the second isolation insulating layer 82-2 and the drain electrode 88 are connected in sequence; the first gate oxide 83 is arranged between the first isolation insulating layer 82-1 and the first gate 84, between the first gate 84 and the second isolation insulating layer 82-2, and between the first gate 84 and the channel 92 of the first lateral gate-all-around transistor.

It should be noted that a junction-less structure can be widely used due to its ability of reducing the gradient of ion concentration and improving the controllability of electrical properties of MOSFET with size below 20 nm. Therefore, in this invention, except for the color difference in the schematic diagram of the source, the drain and channel shown in FIG. 1, the relevant color difference is not shown elsewhere. In addition, the junction-less structure can also be represented in FIG. 1, and the color difference herein does not mean that the ion implantation concentrations of the source, the drain are different from that of the channel.

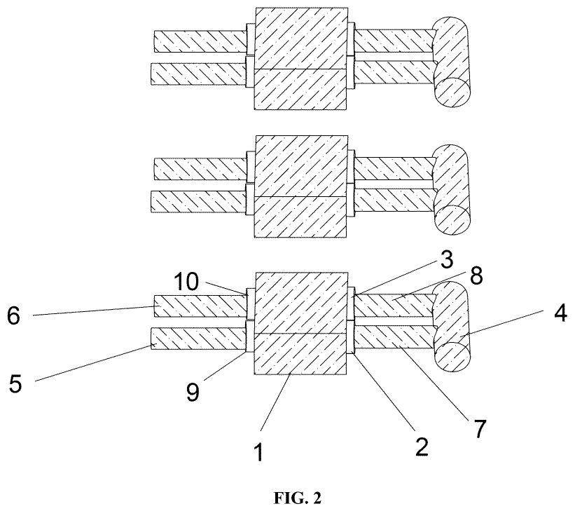

FIG. 2 is one of embodiments of the present disclosure, i.e., a schematic diagram of a three-dimensional integrated circuit with a three-layer superimposed structure of a CMOS phase inverter in a vertical direction, which is composed of vertically superimposed lateral gate-all-around transistors according to the present disclosure. A schematic diagram of a gate connection of PMOS and NMOS in CMOS is indicated by reference number 1. A gate oxide of PMOS is indicated by reference number 3, and a gate oxide of NMOS is indicated by reference number 2. A channel of PMOS is indicated by reference number 10, a channel of NMOS is indicated by reference number 9. A drain of PMOS is indicated by reference number 8, and a drain of NMOS is indicated by reference number 7. A source of PMOS is indicated by reference number 6, and a source of NMOS is indicated by reference number 5. A structure for connecting the gates of PMOS and NMOS, i.e., a signal input terminal, is indicated by reference number 1. A wire for connecting the drains of PMOS and NMOS, i.e., a signal output terminal, is indicated by reference number 4.

Specifically, the CMOS logic device includes three lateral gate-all-around transistor units superimposed in a vertical direction.

The lateral gate-all-around transistor unit includes a gate connection 1 of PMOS and NMOS in CMOS, a gate oxide 2 of NMOS, a gate oxide 3 of PMOS, a wire 4, a source 5 of NMOS, a source 6 of PMOS, a drain 7 of NMOS, a drain 8 of PMOS, a channel 9 of NMOS, and a channel 10 of PMOS. The drain 7 of NMOS is connected with the drain 8 of PMOS through the wire 4, the source 5 of NMOS and the source 6 of PMOS are located on the same side; and the drain 7 of NMOS and the drain 8 of PMOS are located on the same side.

The sources of the three lateral gate-all-around transistor units are located on the same side, and the drains of the three lateral gate-all-around transistor units are located on the same side.

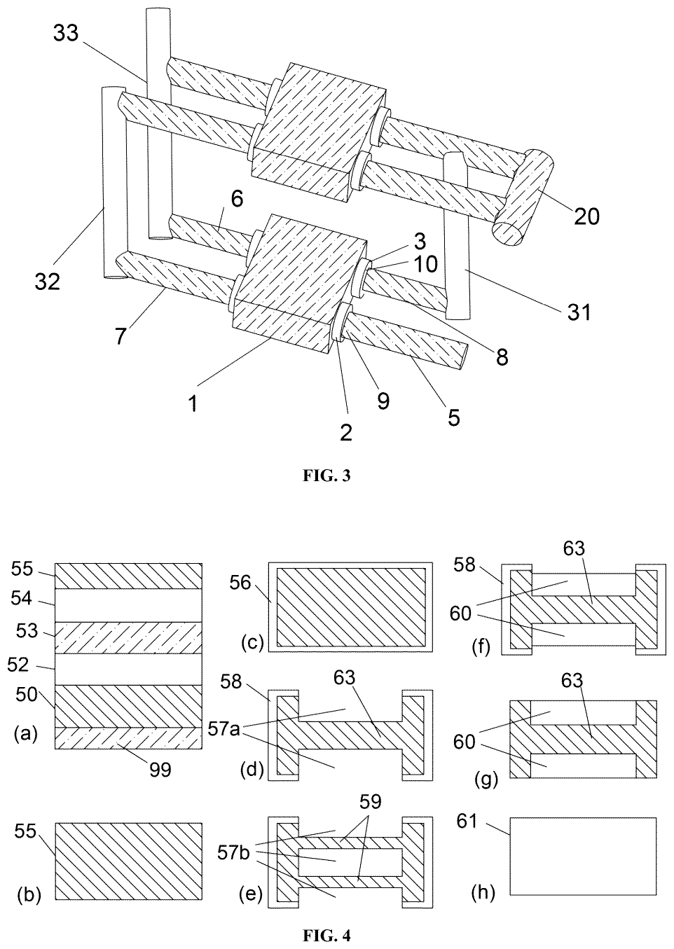

FIG. 3 is one of embodiments of the present disclosure, i.e., a schematic diagram of a three-dimensional CMOS NAND gate composed of vertically superimposed lateral gate-all-around transistors according to the present disclosure. In FIG. 3, a part for connecting the gates of PMOS and NMOS, i.e., two signal input terminals of the NAND gate, is indicated by reference number 1. A signal output terminal is indicated by reference number 20. Connecting wires are indicated by reference numbers 31, 32 and 33. A source, a gate oxide, a channel and a drain of a PMOS are indicated by reference numbers 6, 3, 10 and 8, respectively. A source, a gate oxide, a channel and a drain of a NMOS are indicated by reference numbers 5, 2, 9 and 7, respectively. The source 5 of NMOS and the drain 8 of PMOS are located on the same side; and the source 6 of PMOS and the drain 7 of NMOS are located on the same side. The source 6 of PMOS of one of the lateral gate-all-around transistor units is connected with the drain 7 of NMOS of the same one of the lateral gate-all-around transistors through a signal transmission terminal 20. The drain 8 of PMOS of one of the lateral gate-all-around transistors is connected with the drain 8 of PMOS of another one of the lateral gate-all-around transistors through a first wire 31. The drain 7 of NMOS of one of the lateral gate-all-around transistor units is connected with the drain 7 of NMOS of another one of the lateral gate-all-around transistors through a first wire 32. The source 6 of PMOS of one of the lateral gate-all-around transistors is connected with the source 6 of PMOS of another one of the lateral gate-all-around transistors through a first wire 33.

Specifically, the three-dimensional CMOS NAND logic gate includes two lateral gate-all-around transistor units superimposed in a vertical direction.

The lateral gate-all-around transistor unit includes agate connection 1 between PMOS and NMOS in CMOS, a gate oxide 2 of NMOS, a gate oxide 3 of PMOS, a source 5 of NMOS, a source 6 of PMOS, a drain 7 of NMOS, a drain 8 of PMOS, a channel 9 of NMOS, and a channel 10 of PMOS. The source 5 of NMOS and the drain 8 of PMOS are located on the same side; and the source 6 of PMOS and the drain 7 of NMOS are located on the same side.

The source 6 of PMOS and the drain 7 of NMOS of one of the lateral gate-all-around transistor units are connected through a signal transmission terminal 20.

The drain 8 of PMOS of one of the lateral gate-all-around transistor units is connected with the drain 8 of PMOS of another lateral gate-all-around transistor unit through a first wire 31.

The drain 7 of NMOS of one of the lateral gate-all-around transistor units is connected with the drain 7 of NMOS of another lateral gate-all-around transistor unit through a first wire 32.

The source 6 of PMOS of one of the lateral gate-all-around transistor units is connected with the source 6 of PMOS of another lateral gate-all-around transistor unit through a first wire 33.

It should be noted that the CMOS logic gate is formed by a combination of the MOSFET. As shown in FIG. 3, a NOR gate can be formed if the positions of PMOS and NMOS are changed. In addition, the MOSEFT may also be combined in other ways to form a CMOS logic circuit.

Because SRAM is composed of two CMOSs and two NMOSs, the SRAM can also be formed by combining using the above method.

In the actual large-scale integrated circuit, the above CMOS logic circuit and random access memory SRAM need to be designed and optimized comprehensively by considering factors such as resistance, delay, thermal dispersion, and the cost of preparation process, thus forming a three-dimensional integrated circuit with high performance and high integration level.

Because DRAM requires a capacitor for charging and discharging, if the capacitor can be made small and can be vertically superimposed in three dimensions, the vertically superimposed lateral gate-all-around transistor provided in the present disclosure can also be applied to the three-dimensional DRAM. Compared with the current DRAM with three-dimensionally superimposed chips and wafers, the integration level has been improved by hundreds and thousands of times.

FIG. 4 is a partial process of an embodiment of a manufacturing method for superimposed lateral type gate-all-around transistors, i.e., a schematic diagram of manufacturing a channel pattern of a first layer of multiple layers of superimposed lateral gate-all-around transistors. A substrate is indicated by reference number 99, and the substrate is generally made of silicon material. FIG. 4 (a) is a preliminary process for preparing a channel, mainly including: preparing a sacrificial protective layer SiGe 52, a Si channel layer 53, a sacrificial protective layer SiGe 54 and a Si insulating protective layer 55 on an insulating layer oxide 50, which are used for protecting the channel in early stage and will be etched away in the later stage. FIG. 4 (b) is a schematic diagram of a top of a Si insulating protective layer 55. FIG. 4 (c) shows a Si₃N₄ protective film 56 which is deposited on the Si insulating protective layer 55 of FIG. 4 (b). FIG. 4 (d) is a schematic diagram of etching FIG. 4 (c) to form a single channel 63. FIG. 4 (e) is a schematic diagram of etching FIG. 4 (c) to form double channels 59. The process of the present disclosure can prepare multichannel lateral gate-all-around transistors on each layer, and then the multichannel lateral gate-all-around transistors are superimposed in the vertical direction. For simplicity of explanation, only a superposition structure of single-channel gate-all-around transistors is introduced in the following embodiments. FIG. 4 (f) shows the deposition of a sacrificial protective layer SiGe 60 on an etched part of the single channel of FIG. 4 (d). FIG. 4 (g) shows the etching of the Si₃N₄ protective film 56. FIG. 4 (h) is a diagram showing the deposition and smoothening of a sacrificial protective layer SiGe 61.

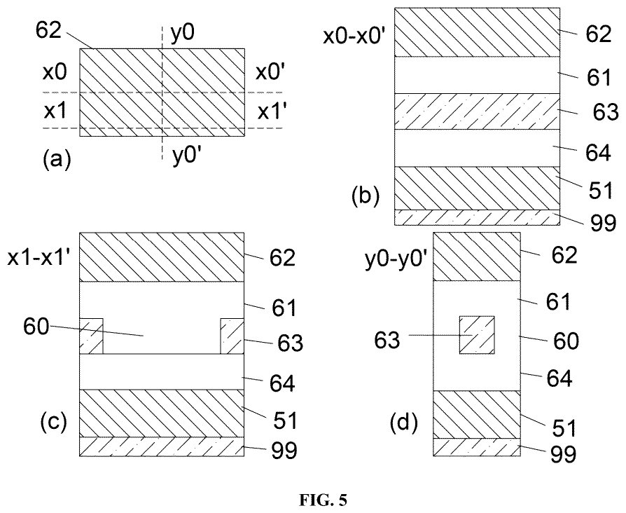

FIG. 5 is a process continuing from FIG. 4 with respect to an embodiment of a manufacturing method for superimposed lateral type gate-all-around transistors according to the present disclosure. FIG. 5 (a) is a schematic diagram of a top after an isolation insulating layer SiO₂ 62 is deposited on the smoothened sacrificial protective layer SiGe 61 formed in FIG. 4 (h).

FIG. 5 (b), FIG. 5 (c) and FIG. 5 (d) show longitudinal sections cut along three directions of x0-x0′, x1-x1′ and y0-y0′ shown in FIG. 5 (a), respectively, where an insulating layer oxide is indicated by reference number 51, sacrificial protective layers SiGe are indicated by reference numbers 64, 60 and 61, and Si channel is indicated by reference number 63.

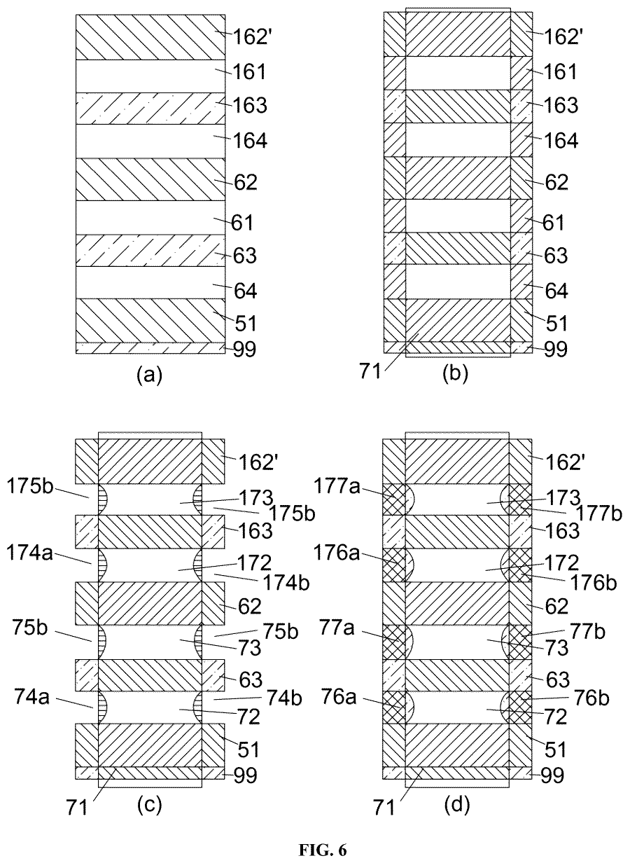

FIG. 6 is a process continuing from FIG. 5 with respect to an embodiment of a manufacturing method for superimposed lateral type gate-all-around transistors according to the present disclosure. FIG. 6 (a) shows a preliminary structure prepared by repeating the steps of FIG. 4 and FIG. 5 for the superposition of two layers of lateral gate-all-around transistors. The sacrificial protective layer SiGe, the Si channel, the sacrificial protective layer SiGe, and a top protection layer, as a structure of an above layer, are indicated by reference numbers 164, 163, 161 and 162′, respectively. If more layers of lateral gate-all-around transistors are continuously superimposed, the top protective layer herein also serves as an isolation insulating layer like the isolation insulating layer SiO₂ 62. FIG. 6(b) shows a layer of Si₃N₄ protective film 71 deposited on a channel part of a structural body of FIG. 6 (a). FIG. 6 (c) is a schematic diagram showing SiGe partly etched away. The etched parts are indicated by reference numbers 74a, 74b, 75a, 75b, 174a, 174b, 175a and 175b, while the remaining parts of SiGe are indicated by reference numbers 72, 73, 172 and 173. FIG. 6 (d) shows polysilicon 76a, 76b, 77a, 77b, 176a, 176b, 177a, 177b deposited at the etched place in FIG. 6(c).

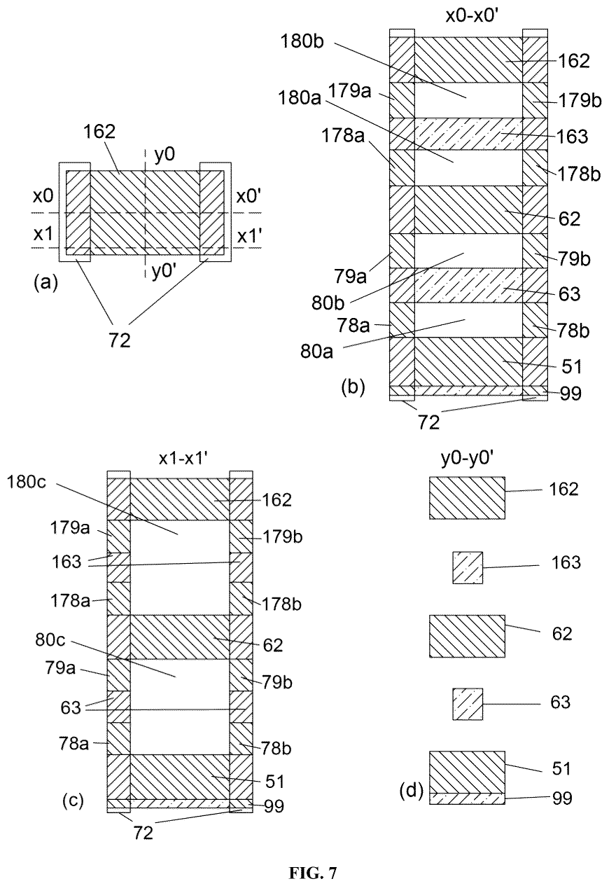

FIG. 7 is a process continuing from FIG. 6 with respect to an embodiment of a manufacturing method for superimposed lateral type gate-all-around transistors according to the present disclosure. FIG. 7 (a) is a schematic diagram showing that firstly the Si₃N₄ protective film 71 used for protecting the channel in FIG. 6 is etched away, and then a top is formed by forming the Si₃N₄ protective film 72 on the source/drain. FIG. 7 (b), FIG. 7 (c) and FIG. 7 (d) are longitudinal sections cut along three directions of x0-x0′, x1-x1′ and y0-y0′ in FIG. 7(a), respectively, showing a structural body formed after the SiGe is etched away again. Due to the adoption of an ion dry etching method, a protruding part of the salient polysilicon in FIG. 6 (d) is also etched away. The etched polysilicon are indicated by reference numbers 78a, 78b, 79a, 79b, 178a, 178b, 179a and 179b. Hole parts after SiGe is etched away are indicated by reference numbers 80c and 180c.

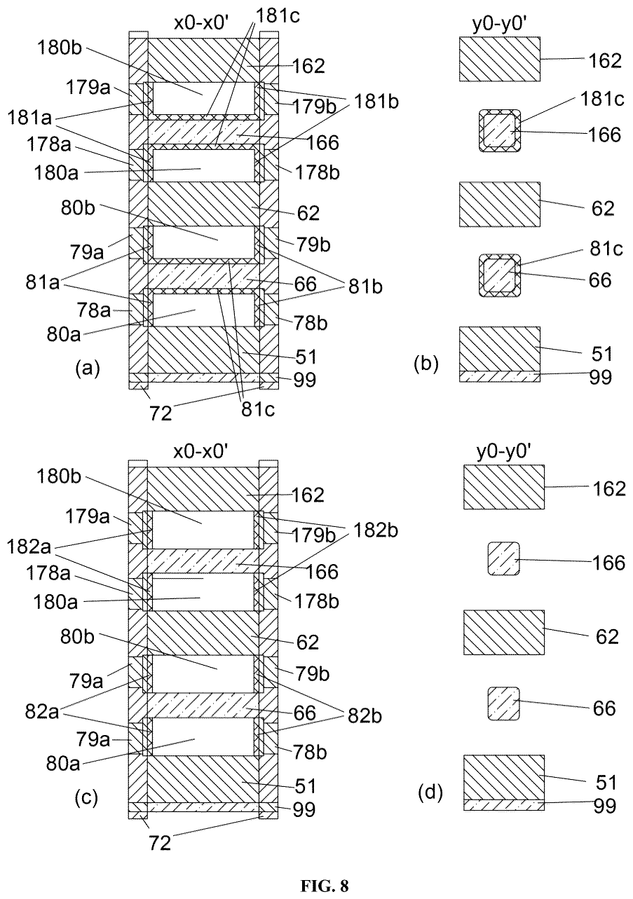

FIG. 8 is a process continuing from FIG. 7 with respect to an embodiment of a manufacturing method for superimposed lateral type gate-all-around transistors according to the present disclosure. FIG. 8(a) and FIG. 8(b) are schematic longitudinal sections cut along the direction of x0-x0′ and y0-y0′, respectively, showing a SiO₂ formed on surfaces of Si channel, Si of the source/drain, and the deposited polysilicon through thermal oxidation. As the channels (66, 166) are usually Si nanowires or nanosheets, the thermal oxidation thereof will produce a self-limiting effect to reduce the oxidation speed, so oxide layers (81c, 181c) around the channels are thinner than those in other parts (81a, 181a, 81b, 181b), and the etching time thereof is shorter. Therefore, by controlling the etching time, after removing the oxide on the surface of the channels, the remaining oxides (82a, 182a, 82b, 182b) can be used and served as an insulating spacer layer between the gate and the source/drain electrode. It should be noted that the thermal oxidation also conduce to adjusting the channel surface. Before thermal oxidation, edges and corners around 63 and 163 in the longitudinal sections of the channel (FIG. 7(d)) will be worn and smoothened to 66 and 166 in FIG. 8(d) after oxidation, which is conducive to improve the conductivity of the channel.

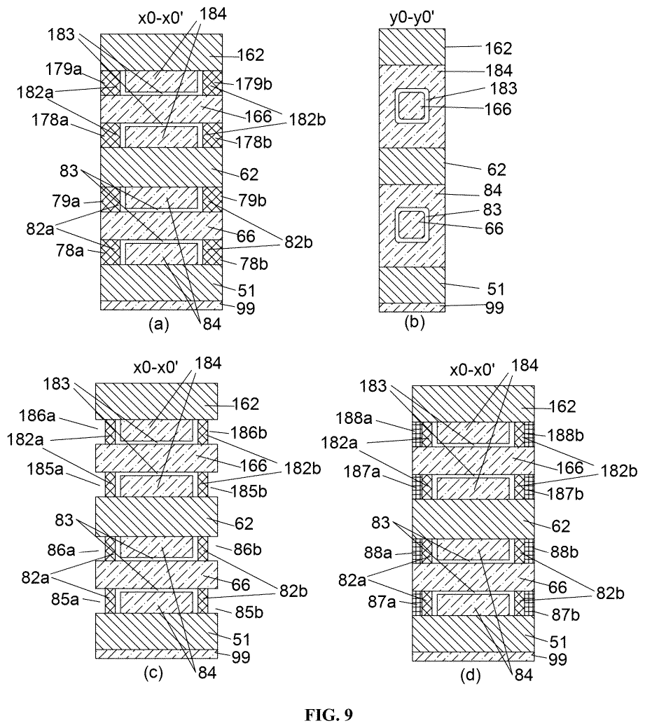

FIG. 9 is a process continuing from FIG. 8 with respect to an embodiment of a manufacturing method for superimposed lateral type gate-all-around transistors according to the present disclosure. FIG. 9 (a) and FIG. 9 (b) are schematic longitudinal sections cut along the directions of x0-x0′ and y0-y0′, respectively, showing that the Si₃N₄ protective film 72 for protecting the source/drain formed in FIG. 7 is removed, and after the gate oxides (83, 183) and the gates (84, 184) are deposited. FIG. 9 (c) is a schematic diagram showing that the polysilicon at the source and drain parts at both ends is etched away after the gate oxide and the gate are formed. FIG. 9 (d) is a schematic diagram after the source and drain electrodes (87a, 187a, 87b, 187b) are deposited in the hole parts in FIG. 9 (c). The gate and the source/drain electrode after deposition may be across the middle insulating isolation layer 66 and connected with each other. Therefore, at the end of the process, it is necessary to etch peripheral sides of the superimposed lateral gate-all-around transistors, which aims to solve the conduction problem between layers. Finally, a connecting wire between the source/drain and gate of each layer and the outside world is formed, and the main process for preparing the superimposed transverse gate-all-around transistors is completed.

Because the MOSFET is almost ubiquitous in integrated circuits, the vertically superimposed lateral gate-all-around transistors, devices composed of the above same, and the manufacturing process thereof can also be prepared and embodied in all parts of integrated circuits, thus helping to achieve a real three-dimensional integrated circuit.

The foregoing embodiments (including structure and process) only describe some embodiments of the present disclosure, and their description is specific, but cannot therefore be understood as a limitation to the patent scope of the present disclosure. It should be noted that for those skilled in the art, several deformations and improvements can be made without departing from the concept of the present disclosure, all of which fall within the scope of protection of the present disclosure. Therefore, the scope of protection of the present disclosure shall be subject to the appended claims.

What is claimed is:

1. A three-dimensional integrated circuit, wherein the three-dimensional integrated circuit has a structural feature that a plurality of layers of lateral gate-all-around metal-oxide-semiconductor field-effect transistors are superimposed and isolated by an insulating isolation layer in a direction perpendicular to a substrate;
the plurality of layers of lateral gate-all-around transistor comprise channels implanted with ions of a same type, and a thickness of the insulating isolation layer for isolating between the plurality of layers of lateral gate-all-around transistors has a thickness that does not exceed 10,000 nanometers.

2. The three-dimensional integrated circuit according to claim 1, wherein channels of the lateral gate-all-around transistors in adjacent layers are parallel to each other and are equal in length; and
a channel in each layer of the lateral gate-all-around transistors is of a multichannel structure, or a single-channel structure.

3. The three-dimensional integrated circuit according to claim 1, wherein when the channel of the lateral gate-all-around transistor in any layer is projected on the substrate to form a plane pattern, a distance between any boundary of the plane pattern parallel to a channel direction and any boundary of a plane pattern, which is formed by projecting a channel of the lateral gate-all-around transistor in adjacent layer on the substrate, parallel to a direction of the channel is less than 500 nanometers.

4. The three-dimensional integrated circuit according to claim 3, wherein the channels of the lateral gate-all-around transistors in the adjacent layers are same in number, shape, size, and ion implantation concentration.

5. The three-dimensional integrated circuit according to claim 1, comprising any one of semiconductor devices with the following connection structures: a semiconductor device formed by connecting the lateral gate-all-around transistors within each layer through a wire;
a semiconductor device formed by connecting between the plurality of layers of lateral gate-all-around transistors through a wire; and
a semiconductor device formed by connecting the lateral gate-all-around transistors within each layer, and the plurality of layers of lateral gate-all-around transistors through wires.

6. The three-dimensional integrated circuit according to claim 1, comprising the substrate, and a bottom insulating layer, a first lateral gate-all-around transistor, an insulating isolation layer, a second lateral gate-all-around transistor, and a cover protective film superimposed on an upper surface of the substrate in sequence.

7. The three-dimensional integrated circuit according to claim 6, wherein the first lateral gate-all-around transistor comprises a central pillar located at a central position of the first lateral gate-all-around transistor, and a cladding layer wrapped outside the central pillar;
the central pillar comprises a channel of the first lateral gate-all-around transistor, a first source, and a first drain; the first source and the first drain are located on both ends of the channel of the first lateral gate-all-around transistor, respectively; the first source, the first drain and the channel of the first lateral gate-all-around transistor are located at the central position of the first lateral gate-all-around transistor;
the cladding layer comprises a first gate oxide, a first gate, a first isolation insulating layer, a second isolation insulating layer, a source electrode, and a drain electrode; the source electrode, the first isolation insulating layer, the first gate, the second isolation insulating layer and the drain electrode are connected in sequence; and the first gate oxide is arranged between the first isolation insulating layer and the first gate, between the first gate and the second isolation insulating layer, and between the first gate and the channel of the first lateral gate-all-around transistor; and
the second lateral gate-all-around transistor has a same structure as the first lateral gate-all-around transistor.

8. A CMOS (Complementary Metal-Oxide-Semiconductor) logic device, comprising three lateral gate-all-around transistor units superimposed in a vertical direction,
wherein each lateral gate-all-around transistor unit comprises a gate connection of PMOS (Positive Metal-Oxide-Semiconductor) and NMOS (N-Metal-Oxide-Semiconductor) in CMOS, a gate oxide of NMOS, a gate oxide of PMOS, a wire, a source of NMOS, a source of PMOS, a drain of NMOS, a drain of PMOS, a channel of NMOS, and a channel of PMOS; the drain of NMOS is connected with the drain of PMOS through the wire, the source of NMOS and the source of PMOS are located on a same side; the drain of NMOS and the drain of PMOS are located on the same side; and
the sources of the three lateral gate-all-around transistor units are located on the same side, and the drains of the three lateral gate-all-around transistor units are located on the same side.

9. A three-dimensional CMOS and non-logic gate, comprising two lateral gate-all-around transistor units superimposed in a vertical direction,
wherein each lateral gate-all-around transistor unit comprises a gate connection of PMOS and NMOS in CMOS, a gate oxide of NMOS, a gate oxide of PMOS, a source of NMOS, a source of PMOS, a drain of NMOS, a drain of PMOS, a channel of NMOS, and a channel of PMOS; the source of NMOS and the drain of PMOS are located on the same side; the source of PMOS and the drain of NMOS are located on the same side;
the source of PMOS and the drain of NMOS of one of the lateral gate-all-around transistor units are connected through a signal transmission terminal;
the drain of PMOS of one of the lateral gate-all-around transistor units and the drain of PMOS of another lateral gate-all-around transistor units are connected through a first wire;
the drain of NMOS of one of the lateral gate-all-around transistor units and the drain of NMOS of another lateral gate-all-around transistor units are connected through a first wire; and
the source of PMOS of one of the lateral gate-all-around transistor units and the source of PMOS of another lateral gate-all-around transistor units are connected through a first wire.

10. A manufacturing method for the three-dimensional integrated circuit according to claim 1, comprising the following steps:
1.1. depositing an insulating layer on a substrate;
1.2. depositing a sacrificial protective layer on the insulating layer, depositing a channel layer doped with ions on the sacrificial protective layer, and depositing a sacrificial protective layer on the channel layer doped with ions;
1.3. depositing an insulating protective layer on the sacrificial protective layer;
1.4. forming a required channel pattern on a structural body in Step 1.3 through a process of semiconductor etching;
1.5. depositing the sacrificial protective layer in Step 1.2 on the structural body in Step 1.3, wearing and smoothening the sacrificial protective layer until an upper surface of the structural body in Step 1.3 is completely covered with the sacrificial protective layer;
1.6. depositing an insulating isolation layer on the worn and smoothened sacrificial protective layer;
1.7. repeating the above steps from 1.2 to 1.6 to form a basic framework with a required number of layers;
1.8. depositing a protective film to protect a channel part in a middle of the basic framework;
1.9. etching away a sacrificial protective layer exposed out of the protective film at both ends of a structural body in Step 1.8;
1.10. depositing polysilicon on a part etched in Step 1.9;
1.11. depositing the same protective film as that in Step 1.8 on a structural body in Step 1.10 for protection;
1.12. etching away a protective film at a middle channel part;
1.13. etching away the sacrificial protective layer around the middle channel part;
1.14. forming an insulating spacer layer between a gate and a source/drain electrode;
1.15. forming a gate oxide;
1.16. forming a gate;
1.17. protecting a structure formed in Step 1.16 with the same protective film as in Step 1.11;
1.18. etching away a protective film at both ends;
1.19. etching away the polysilicon formed in Step 1.10;
1.20. forming a source/drain electrode at a hole left after etching in Step 1.19;
1.21. etching a periphery of a structure body formed in Step 1.20, on a plane parallel to the substrate, to remove a connecting and conducting part between layers when the gate is deposited in Step 1.16 and when the source/drain electrode is deposited in Step 1.20, thus forming a plurality of layers of lateral gate-all-around transistors isolated by the insulating isolation layer formed in Step 1.6;
1.22. wrapping a structure in Step 1.21 with an insulating material; and
1.23. forming a connecting wire between the layers of lateral gate-all-around transistors and the outside world using a semiconductor etch technology, thus forming a final structure with a plurality of layers of gate-all-around transistors.

11. The manufacturing method for the three-dimensional integrated circuit according to claim 10, wherein forming an insulating spacer layer between the gate and the drain/source electrode is as follows: depositing polysilicon around the source/drain, wherein one end, close to the channel, of polysilicon is configured for thermal oxidation to form an insulating spacer layer between the gate and the source/drain electrode, and another end of the polysilicon is etched away for depositing the source/drain electrode in the later stage of the process.

12. The manufacturing method for the three-dimensional integrated circuit according to claim 11, wherein after the thermal oxidation, the method further comprises removing oxide on a surface of nanowires, and forming an insulating spacer layer between the gate and the source/drain electrode using residual oxide.

13. The three-dimensional integrated circuit according to any one of claim 2, comprising the substrate, and a bottom insulating layer, a first lateral gate-all-around transistor, an insulating isolation layer, a second lateral gate-all-around transistor, and a cover protective film superimposed on an upper surface of the substrate in sequence.

14. The three-dimensional integrated circuit according to claim 13, wherein the first lateral gate-all-around transistor comprises a central pillar located at a central position of the first lateral gate-all-around transistor, and a cladding layer wrapped outside the central pillar;
the central pillar comprises a channel of the first lateral gate-all-around transistor, a first source, and a first drain; the first source and the first drain are located on both ends of the channel of the first lateral gate-all-around transistor, respectively; the first source, the first drain and the channel of the first lateral gate-all-around transistor are located at the central position of the first lateral gate-all-around transistor;
the cladding layer comprises a first gate oxide, a first gate, a first isolation insulating layer, a second isolation insulating layer, a source electrode, and a drain electrode; the source electrode, the first isolation insulating layer, the first gate, the second isolation insulating layer and the drain electrode are connected in sequence; and the first gate oxide is arranged between the first isolation insulating layer and the first gate, between the first gate and the second isolation insulating layer, and between the first gate and the channel of the first lateral gate-all-around transistor; and
the second lateral gate-all-around transistor has a same structure as the first lateral gate-all-around transistor.

15. The three-dimensional integrated circuit according to any one of claim 3, comprising the substrate, and a bottom insulating layer, a first lateral gate-all-around transistor, an insulating isolation layer, a second lateral gate-all-around transistor, and a cover protective film superimposed on an upper surface of the substrate in sequence.

16. The three-dimensional integrated circuit according to claim 15, wherein the first lateral gate-all-around transistor comprises a central pillar located at a central position of the first lateral gate-all-around transistor, and a cladding layer wrapped outside the central pillar;
the central pillar comprises a channel of the first lateral gate-all-around transistor, a first source, and a first drain; the first source and the first drain are located on both ends of the channel of the first lateral gate-all-around transistor, respectively; the first source, the first drain and the channel of the first lateral gate-all-around transistor are located at the central position of the first lateral gate-all-around transistor;
the cladding layer comprises a first gate oxide, a first gate, a first isolation insulating layer, a second isolation insulating layer, a source electrode, and a drain electrode; the source electrode, the first isolation insulating layer, the first gate, the second isolation insulating layer and the drain electrode are connected in sequence; and the first gate oxide is arranged between the first isolation insulating layer and the first gate, between the first gate and the second isolation insulating layer, and between the first gate and the channel of the first lateral gate-all-around transistor; and
the second lateral gate-all-around transistor has a same structure as the first lateral gate-all-around transistor.

17. The three-dimensional integrated circuit according to any one of claim 4, comprising the substrate, and a bottom insulating layer, a first lateral gate-all-around transistor, an insulating isolation layer, a second lateral gate-all-around transistor, and a cover protective film superimposed on an upper surface of the substrate in sequence.

18. The three-dimensional integrated circuit according to claim 17, wherein the first lateral gate-all-around transistor comprises a central pillar located at a central position of the first lateral gate-all-around transistor, and a cladding layer wrapped outside the central pillar;
the central pillar comprises a channel of the first lateral gate-all-around transistor, a first source, and a first drain; the first source and the first drain are located on both ends of the channel of the first lateral gate-all-around transistor, respectively; the first source, the first drain and the channel of the first lateral gate-all-around transistor are located at the central position of the first lateral gate-all-around transistor;
the cladding layer comprises a first gate oxide, a first gate, a first isolation insulating layer, a second isolation insulating layer, a source electrode, and a drain electrode; the source electrode, the first isolation insulating layer, the first gate, the second isolation insulating layer and the drain electrode are connected in sequence; and the first gate oxide is arranged between the first isolation insulating layer and the first gate, between the first gate and the second isolation insulating layer, and between the first gate and the channel of the first lateral gate-all-around transistor; and
the second lateral gate-all-around transistor has a same structure as the first lateral gate-all-around transistor.

19. The three-dimensional integrated circuit according to any one of claim 5, comprising the substrate, and a bottom insulating layer, a first lateral gate-all-around transistor, an insulating isolation layer, a second lateral gate-all-around transistor, and a cover protective film superimposed on an upper surface of the substrate in sequence.

20. The three-dimensional integrated circuit according to claim 19, wherein the first lateral gate-all-around transistor comprises a central pillar located at a central position of the first lateral gate-all-around transistor, and a cladding layer wrapped outside the central pillar;
the central pillar comprises a channel of the first lateral gate-all-around transistor, a first source, and a first drain; the first source and the first drain are located on both ends of the channel of the first lateral gate-all-around transistor, respectively; the first source, the first drain and the channel of the first lateral gate-all-around transistor are located at the central position of the first lateral gate-all-around transistor;
the cladding layer comprises a first gate oxide, a first gate, a first isolation insulating layer, a second isolation insulating layer, a source electrode and a drain electrode; the source electrode, the first isolation insulating layer, the first gate, the second isolation insulating layer and the drain electrode are connected in sequence; and the first gate oxide is arranged between the first isolation insulating layer and the first gate, between the first gate and the second isolation insulating layer, and between the first gate and the channel of the first lateral gate-all-around transistor; and
the second lateral gate-all-around transistor has a same structure as the first lateral gate-all-around transistor.
